(19) United States
(12) Patent Application Publication
(10) Pub. No.: US 2026/0324343 A1
(43) Pub. Date: Oct. 15, 2026

(54) ASSEMBLY JIG FOR POWER CONVERTER AND METHOD FOR MANUFACTURING POWER CONVERTER

(71) Applicant: TMEIC Corporation, Tokyo (JP)

(72) Inventors: Hirotaka MOTOBAYASHI, Chuo-ku (JP); Ikuto UDAGAWA, Chuo-ku (JP); Shigeyuki NAKABAYASHI, Chuo-ku (JP)

(73) Assignee: TMEIC Corporation, Tokyo (JP)

(21) Appl. No.: 19/108,558

(22) PCT Filed: Sep. 16, 2022
(86) PCT No.: PCT/JP2022/034774

§ 371 Date: Mar. 4, 2025

(51) Int. Cl. H10P 72/00; H10W 40/00

(52) U.S. Cl. CPC H10P 72/0438; H10W 40/037

(57) ABSTRACT

An assembly jig for a power converter includes a pair of fixing portions disposed to face each other in a first direction orthogonal to a vertical direction, and a support fitting supporting a heat dissipation plate and a power semiconductor element to be alternately laminated and arranged in the first direction between a pair of insulating frames in an attached state where the support fitting is attached to the pair of insulating frames fixed to the pair of fixing portions so as to face each other in a second direction orthogonal to the vertical direction and the first direction, in which support fitting includes a guide to guide movement of the heat dissipation plate and the power semiconductor element in the first direction when the heat dissipation plate and the power semiconductor element having been laminated and arranged are pressure-bonded to each other in the first direction.

### TECHNICAL FIELD

The present disclosure relates to an assembly jig for a power converter and a method for manufacturing the power converter.

### BACKGROUND ART

Conventionally, as a power converter that handles large electric power, as disclosed in Japanese Patent Laying-Open No. 2003-168778 (PTL 1), a configuration is known in which a multilayer body in which a plurality of semiconductor elements and a plurality of heat sinks are alternately laminated in a vertical direction is sandwiched between an upper pressure support plate and a lower pressure support plate.

A spherical seat and a disc spring are disposed between the multilayer body and the upper pressure support plate, and an insulating rod penetrating the upper pressure support plate and the lower pressure support plate is disposed outside the multilayer body. By adjusting a fastening force of a fastening member that fastens the insulating rod to the upper pressure support plate and the lower pressure support plate, a pressure bonding force that pressure-bonds the multilayer body is adjusted by the upper pressure support plate and the lower pressure support plate.

### CITATION LIST

### Patent Literature

PTL 1: Japanese Patent Laying-Open No. 2003-168778

### SUMMARY OF INVENTION

### Technical Problem

However, in the power converter disclosed in PTL 1, the plurality of semiconductor elements and the plurality of heat sinks are alternately laminated in the vertical direction. Therefore, when the power converter is assembled, there is a concern that the plurality of semiconductor elements and the plurality of heat sinks fall during or after lamination. In addition, since the plurality of semiconductor elements and the plurality of heat sinks are laminated while being balanced so as not to fall, it is difficult to assemble.

The present disclosure has been made in view of the above problems, and an object of the present disclosure is to provide an assembly jig for a power converter and a method for manufacturing the power converter capable of improving safety and workability of assembly.

### Solution to Problem

An assembly jig for a power converter according to the present disclosure includes a pair of fixing portions disposed to face each other in a first direction orthogonal to a vertical direction, and a support fitting provided so as to be attachable from below to a pair of insulating frames fixed to the pair of fixing portions so as to face each other in a second direction orthogonal to the vertical direction and the first direction, the support fitting supporting a heat dissipation plate and a power semiconductor element to be alternately laminated and arranged in the first direction between the pair of insulating frames in an attached state where the support fitting is attached to the pair of insulating frames. The support fitting includes a guide to guide movement of the heat dissipation plate and the power semiconductor element in the first direction when the heat dissipation plate and the power semiconductor element having been laminated and arranged are pressure-bonded to each other in the first direction.

The assembly jig for a power converter according to the present disclosure may further include a positioning member to be detachably attached to the support fitting and determine a position where at least the heat dissipation plate is disposed in a state where the positioning member is attached to the support fitting.

The assembly jig for a power converter according to the present disclosure may further include a foundation to support the pair of fixing portions. In this case, the foundation may be provided with a support fitting attachment portion to attach and store the support fitting, and a positioning member attachment portion to attach and store the positioning member.

The assembly jig for a power converter according to the present disclosure may further include a foundation to support the pair of fixing portions. In this case, the foundation may include a first unit that is located on one side in the first direction and supports one of the pair of fixing portions, a second unit that is located on the other side in the first direction and supports the other one of the pair of fixing portions, and a lock mechanism. Furthermore, in this case, the first unit is preferably provided to be relatively slidable against the second unit in the first direction, and the lock mechanism is preferably provided to be switchable between a state that enables the first unit to relatively slide and a state that disables the first unit to relatively slide.

The assembly jig for a power converter according to the present disclosure may further include a foundation to support the pair of fixing portions, and the foundation may include a portion located below the support fitting in the attached state. In this case, in the pressure-bonded state where pressure bonding mechanisms are attached to both ends of the support fitting in the first direction between the pair of insulating frames and the heat dissipation plate and the power semiconductor element are pressure-bonded to each other in the first direction between the pressure bonding mechanisms in the first direction, a portion of the pressure bonding mechanism located on one side in the first direction and the fixing portion of the pair of fixing portions located on the one side in the first direction are preferably disposed side by side in the first direction with a secured distance longer than or equal to a spatial distance for insulating parts having mutually different potentials. A portion of the pressure bonding mechanism located on the other side in the first direction and the fixing portion of the pair of fixing portions located on the other side in the first direction are preferably disposed side by side in the first direction with a secured distance longer than or equal to a spatial distance for insulating parts having mutually different potentials. Furthermore, the heat dissipation plate and the portion of the foundation located below the support fitting are preferably disposed with a secured distance longer than or equal to a spatial distance for insulating parts having mutually different potentials in the vertical direction.

A method for manufacturing a power converter according to the present disclosure includes fixing a pair of insulating frames to a pair of fixing portions disposed to face each other in a first direction orthogonal to a vertical direction so as to face each other in a second direction orthogonal to the vertical direction and the first direction, attaching a support fitting from below to the pair of insulating frames fixed to the pair of fixing portions, attaching pressure bonding mechanisms to both ends of the support fitting in the first direction between the pair of insulating frames, alternately laminating and arranging a heat dissipation plate and a power semiconductor element on the support fitting in the first direction between the pair of insulating frames and between the pressure bonding mechanisms in the first direction, and pressure-bonding the heat dissipation plate and the power semiconductor element that are laminated and arranged on the support fitting to each other in the first direction by the pressure bonding mechanisms. In the pressure-bonding, movement of the heat dissipation plate and the power semiconductor element in the first direction is guided by a guide included in the support fitting.

The method for manufacturing a power converter according to the present disclosure may further include attaching a positioning member to determine a position where at least the heat dissipation plate is disposed to the support fitting attached to the pair of insulating frames. In this case, the laminating and arranging may include arranging the heat dissipation plates along the first direction at a predetermined interval by using the positioning member, and arranging the power semiconductor element in each gap between the heat dissipation plates adjacent to each other in the first direction.

The method for manufacturing a power converter according to the present disclosure preferably includes detaching the positioning member from the support fitting before the pressure-bonding.

In the method for manufacturing a power converter according to the present disclosure, the power semiconductor element may include a protrusion to protrude in the first direction, and the heat dissipation plate may include a groove to extend in the vertical direction. In this case, in the arranging of the power semiconductor element in the each gap between the heat dissipation plates adjacent to each other in the first direction, the protrusion is preferably inserted into the groove to guide movement of the power semiconductor element in the vertical direction.

In the method for manufacturing a power converter according to the present disclosure, in the fixing of the pair of insulating frames, an assembly jig having the pair of fixing portions and a foundation to support the pair of fixing portions may be used. The foundation may include a portion located below the support fitting in an attached state where the support fitting is attached to the pair of insulating frames. In this case, in the pressure-bonding, in a pressure-bonded state where the heat dissipation plate and the power semiconductor element having been laminated and arranged on the support fitting are pressure-bonded to each other in the first direction by the pressure bonding mechanism, a portion of the pressure bonding mechanism located on one side in the first direction and the fixing portion of the pair of fixing portions located on the one side in the first direction are preferably disposed side by side in the first direction with a secured distance longer than or equal to a spatial distance for insulating parts having mutually different potentials. A portion of the pressure bonding mechanism located on the other side in the first direction and the fixing portion of the pair of fixing portions located on the other side in the first direction are preferably disposed side by side in the first direction with a secured distance longer than or equal to a spatial distance for insulating parts having mutually different potentials. Furthermore, the heat dissipation plate and the portion of the foundation located below the support fitting are preferably disposed with a secured distance longer than or equal to a spatial distance for insulating parts having mutually different potentials in the vertical direction.

### Advantageous Effects of Invention

It is possible to provide an assembly jig for a power converter and a method for manufacturing the power converter capable of improving safety and workability of assembly.

### BRIEF DESCRIPTION OF DRAWINGS

FIG. 1 is a perspective view of an assembly jig for a power converter according to an embodiment.

FIG. 2 is an exploded perspective view of a support unit in the assembly jig for the power converter according to the embodiment.

FIG. 3 is a view of a support fitting according to the embodiment as viewed from a back surface.

FIG. 4 is a view for describing an operation when a foundation of the assembly jig for the power converter according to the embodiment is made compact.

FIG. 5 is a view illustrating a state where the assembly jig for the power converter according to the embodiment is made compact.

FIG. 6 is a flowchart illustrating steps of manufacturing the power converter according to the embodiment.

FIG. 7 is a view illustrating a step of fixing a pair of insulating frames illustrated in FIG. 6.

FIG. 8 is a view illustrating a step of attaching the support fitting illustrated in FIG. 6.

FIG. 9 is a view illustrating a step of attaching a positioning member illustrated in FIG. 6.

FIG. 10 is a view illustrating a step of fixing a reinforcing frame illustrated in FIG. 6.

FIG. 11 is a view illustrating a first step of a step of attaching a pressure bonding mechanism illustrated in FIG. 6.

FIG. 12 is a perspective view illustrating a heat dissipation plate used in the power converter according to the embodiment.

FIG. 13 is a view illustrating a second step of the step of attaching the pressure bonding mechanism illustrated in FIG. 6.

FIG. 14 is a view illustrating a first step of a step of laminating and arranging the heat dissipation plate and a power semiconductor element illustrated in FIG. 6.

FIG. 15 is a perspective view illustrating the power semiconductor element used in the power converter according to the embodiment.

FIG. 16 is a view illustrating a second step of the step of laminating and arranging the heat dissipation plate and the power semiconductor element illustrated in FIG. 6.

FIG. 17 is a view illustrating a step of detaching the positioning member illustrated in FIG. 6.

FIG. 18 is a view illustrating a step of pressure-bonding the heat dissipation plate and the power semiconductor element having been laminated and arranged, illustrated in FIG. 6.

FIG. 19 is a side view illustrating a state after the step of pressure-bonding illustrated in FIG. 6.

### DESCRIPTION OF EMBODIMENTS

Hereinafter, an embodiment of the present disclosure will be described in detail with reference to the drawings. In the following embodiment, the same or common portions are denoted by the same reference signs in the drawings, and the description thereof will not be repeated.

### (Effects of Assembly Jig for Power Converter)

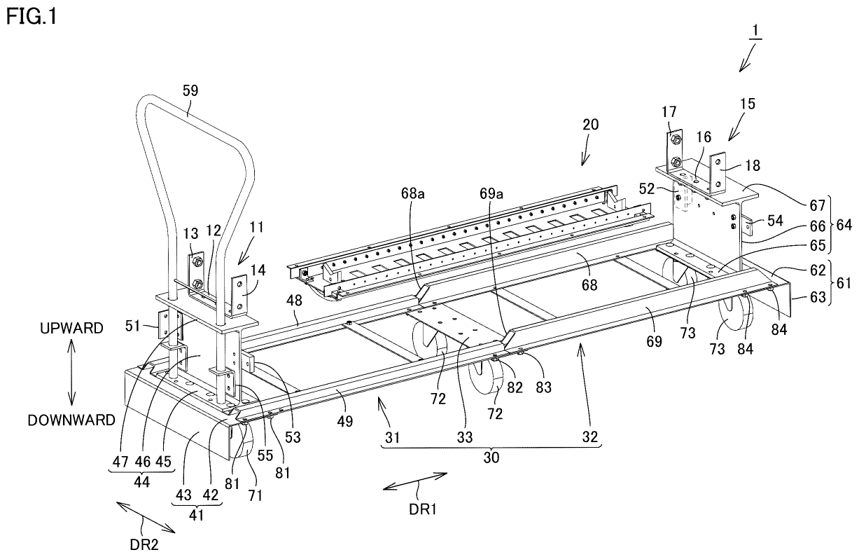

FIG. 1 is a perspective view of an assembly jig for a power converter according to the embodiment. An assembly jig 1 for a power converter according to the embodiment will be described with reference to FIG. 1.

Assembly jig 1 includes a pair of fixing portions 11 and 15, a support unit 20, and a foundation 30.

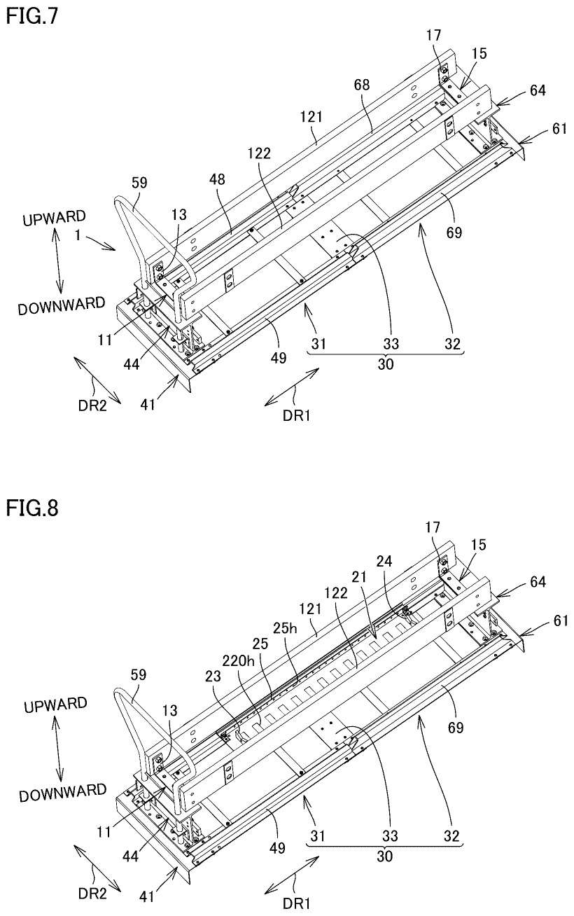

The pair of fixing portions 11 and 15 is a part for fixing a pair of insulating frames 121 and 122 (see FIG. 7) of a power converter 200 (described later) (see FIG. 19). The pair of fixing portions 11 and 15 is disposed to face each other in a first direction (DR1 direction) orthogonal to a vertical direction. The pair of fixing portions 11 and 15 is disposed apart from each other in the first direction. The pair of fixing portions 11 and 15 is supported by foundation 30.

Fixing portion 11 is located on one side in the first direction. Fixing portion 11 includes a flat plate 12 and side walls 13 and 14.

Flat plate 12 has a thickness in the vertical direction and extends in a second direction (DR2 direction) orthogonal to the vertical direction and the first direction. Side wall 13 has a thickness in the second direction and extends upward from one end of flat plate 12 in the second direction. Side wall 14 has a thickness in the second direction and extends upward from the other end of flat plate 12 in the second direction. Side walls 13 and 14 are disposed so as to face each other in the second direction. Side walls 13 and 14 are disposed apart from each other in the second direction.

Fixing portion 15 is located on the other side in the first direction. Fixing portion 15 includes a flat plate 16 and side walls 17 and 18.

Flat plate 16 has a thickness in the vertical direction and extends in the second direction. Side wall 17 has a thickness in the second direction and extends upward from one end of flat plate 16 in the second direction. Side wall 18 has a thickness in the second direction and extends upward from the other end of flat plate 16 in the second direction. Side walls 17 and 18 are disposed so as to face each other in the second direction. Side walls 17 and 18 are disposed apart from each other in the second direction.

Foundation 30 supports the pair of fixing portions 11 and 15. Foundation 30 includes a first unit 31, a second unit 32, a connection member 33, and a plurality of casters 71, 72, and 73. Foundation 30 is movable by the plurality of casters 71, 72, and 73.

First unit 31 is located on one side in the first direction and supports fixing portion 11 which is one of the pair of fixing portions. First unit 31 includes a base 41, a support base 44, and a pair of longitudinal members 48 and 49.

Base 41 supports support base 44. Base 41 includes a flat plate 42 and a side wall 43. Flat plate 42 has a thickness in the vertical direction and extends in the second direction. Side wall 43 has a thickness in the first direction and extends downward from an end of flat plate 42 on one side in the first direction. Caster 71 is fixed to a lower surface of flat plate 42. Side wall 43 faces caster 71 from outside in the first direction.

Support base 44 includes a bottom plate 45, an upright wall 46, and an upper plate 47. Bottom plate 45 has a thickness in the vertical direction and extends in the second direction. Bottom plate 45 is fixed to an upper surface of flat plate 42. Upper plate 47 has a thickness in the vertical direction and extends in the second direction. Upper plate 47 faces bottom plate 45 in the vertical direction. Upper plate 47 is disposed above bottom plate 45. Fixing portion 11 is fixed to an upper surface of upper plate 47.

Upright wall 46 has a thickness in the first direction and extends upward from a center of bottom plate 45 in the first direction. Upright wall 46 connects the center of bottom plate 45 in the first direction and a center of upper plate 47 in the first direction.

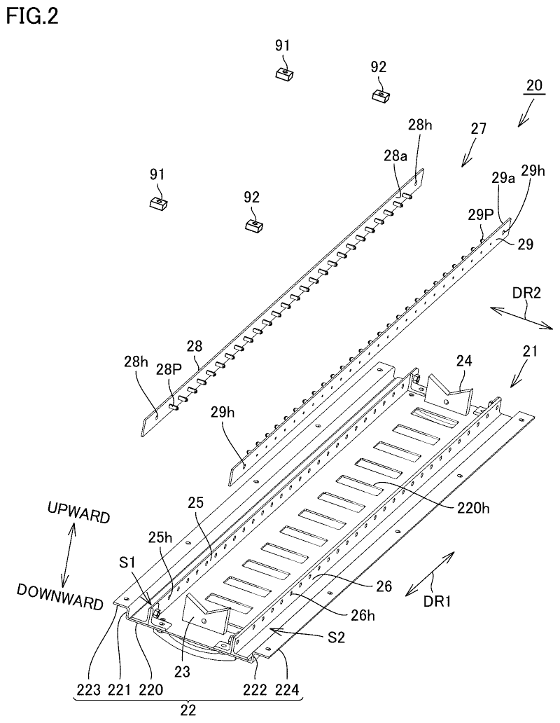

Upright wall 46 is provided with a positioning member attachment portion 51 and a support fitting attachment portion 53. Positioning member attachment portion 51 is for attaching and storing a positioning member 27 (described later) (see FIG. 2). Support fitting attachment portion 53 is for attaching and storing a support fitting 21 (described later) (see FIG. 2).

Positioning member attachment portion 51 and support fitting attachment portion 53 are provided so that positioning member 27 and support fitting 21 do not interfere with each other in a state where positioning member 27 and support fitting 21 are attached.

Specifically, positioning member attachment portion 51 is provided on an end of upright wall 46 located on one side in the second direction. Support fitting attachment portion 53 is provided on an end of upright wall 46 located on the other side in the second direction.

The pair of longitudinal members 48 and 49 extends along the first direction. The pair of longitudinal members 48 and 49 is disposed to face each other in the second direction. The pair of longitudinal members 48 and 49 is disposed apart from each other in the second direction.

One end of the pair of longitudinal members 48 and 49 in the first direction is fixed to flat plate 42 by a fastening member 81. The other end of the pair of longitudinal members 48 and 49 in the first direction is fixed to connection member 33 by a fastening member 82. Specifically, the other end of the pair of longitudinal members 48 and 49 is fixed to an end of connection member 33 located on one side in the first direction.

Fastening member 82 functions as a lock mechanism. The lock mechanism is provided to be switchable between a state that enables first unit 31 to relatively slide against the second unit and a state that disables first unit 31 to relatively slide against the second unit.

That is, in a state where the other end of the pair of longitudinal members 48 and 49 is fastened to connection member 33 by fastening member 82, first unit 31 is unable to relatively slide. On the other hand, in a state where the fastening of the pair of longitudinal members 48 and 49 by fastening member 82 is released, first unit 31 is able to relatively slide.

Second unit 32 is located on the other side in the first direction and supports fixing portion 15 that is the other one of the pair of fixing portions. Second unit 32 includes a base 61, a support base 64, and a pair of longitudinal members 68 and 69.

Base 61 supports support base 64. Base 61 includes a flat plate 62 and a side wall 63. Flat plate 62 has a thickness in the vertical direction and extends in the second direction. Side wall 63 has a thickness in the first direction and extends downward from an end of flat plate 62 on the other side in the first direction. Caster 73 is fixed to the lower surface of flat plate 42. Side wall 63 faces caster 73 from outside in the first direction.

Support base 64 includes a bottom plate 65, an upright wall 66, and an upper plate 67. Bottom plate 65 has a thickness in the vertical direction and extends in the second direction. Bottom plate 65 is fixed to an upper surface of flat plate 62. Upper plate 67 has a thickness in the vertical direction and extends in the second direction. Upper plate 67 faces bottom plate 65 in the vertical direction. Upper plate 67 is disposed above bottom plate 65. Fixing portion 15 is fixed to an upper surface of upper plate 67.

Upright wall 66 extends upward from a center of bottom plate 65 in the first direction. Upright wall 66 connects the center of bottom plate 65 in the first direction and a center of upper plate 67 in the first direction.

Upright wall 66 is provided with a positioning member attachment portion 52 and a support fitting attachment portion 54. Positioning member attachment portion 52 is for attaching and storing positioning member 27 (see FIG. 2). Support fitting attachment portion 54 is for attaching and storing support fitting 21 (see FIG. 2).

Positioning member attachment portion 52 and support fitting attachment portion 54 are provided so that positioning member 27 and support fitting 21 do not interfere with each other in a state where positioning member 27 and support fitting 21 are attached.

Specifically, positioning member attachment portion 52 is provided on an end of upright wall 66 located on one side in the second direction. Support fitting attachment portion 54 is provided on an end of upright wall 66 located on the other side in the second direction.

The pair of longitudinal members 68 and 69 extends along the first direction. The pair of longitudinal members 68 and 69 is disposed to face each other in the second direction. The pair of longitudinal members 68 and 69 is disposed apart from each other in the second direction.

One end of the pair of longitudinal members 68 and 69 in the first direction is fixed to an end of connection member 33 located on the other side in the first direction. The other end of the pair of longitudinal members 68 and 69 in the first direction is fixed to flat plate 62 by a fastening member 84.

Slopes 68a and 69a are provided on one end of the pair of longitudinal members 68 and 69 in the first direction. Slopes 68a and 69a are inclined downward toward one side in the first direction. When first unit 31 is moved toward second unit 32, Slopes 68a and 69a guide the movement of the pair of longitudinal members 48 and 49.

Connection member 33 connects first unit 31 and second unit 32. Specifically, as described above, since the other end of the pair of longitudinal members 48 and 49 in the first direction and one end of the pair of longitudinal members 68 and 69 in the first direction are fixed to connection member 33, connection member 33 connects first unit 31 and second unit 32. Caster 72 is fixed to a lower surface of connection member 33.

Connection member 33 has a flat plate shape having a thickness in the vertical direction. As will be described later, the connection member 33 is located below support fitting 21 in a state where power converter 200 has been assembled by using assembly jig 1.

FIG. 2 is an exploded perspective view of the support unit in the assembly jig for the power converter according to the embodiment. Support unit 20 will be described with reference to FIG. 2.

Support unit 20 includes support fitting 21, positioning member 27, and a pair of fixing members 91 and 92. That is, assembly jig 1 includes support fitting 21, positioning member 27, and the pair of fixing members 91 and 92.

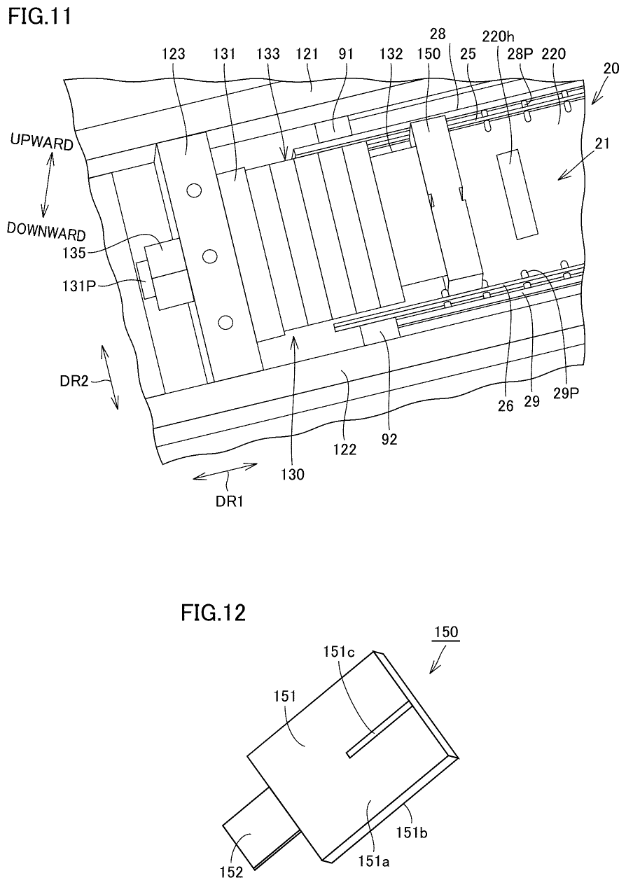

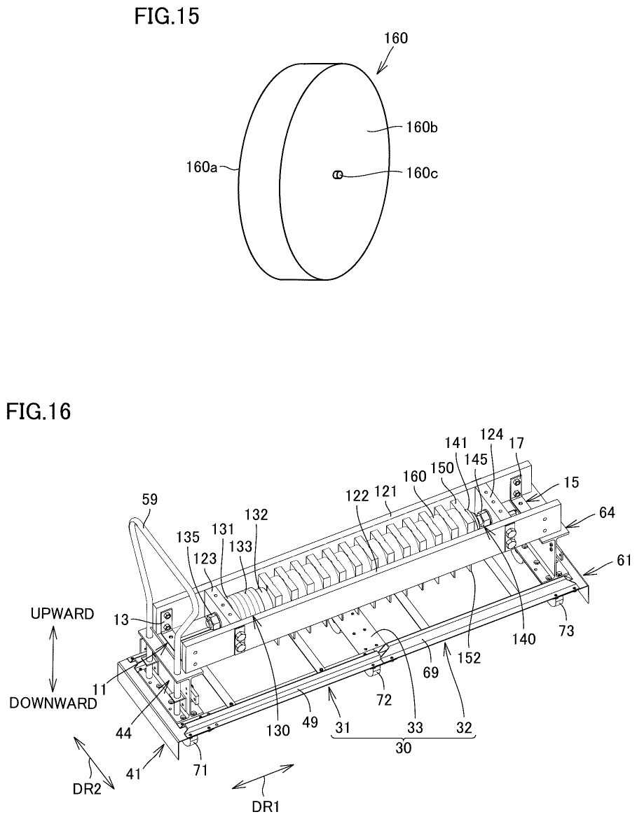

Support fitting 21 is provided to be attachable to the pair of insulating frames 121 and 122 fixed to the pair of fixing portions 11 and 15 from below. Support fitting 21 supports heat dissipation plates 150 (see FIG. 12) and power semiconductor elements (see FIG. 15) alternately laminated in the first direction in an attached state where support fitting 21 is attached to the pair of insulating frames 121 and 122.

Support fitting 21 includes a body 22, pressure bonding mechanism supports 23 and 24, and guides 25 and 26. Body 22 includes a plate 220, side walls 221 and 222, and flanges 223 and 224.

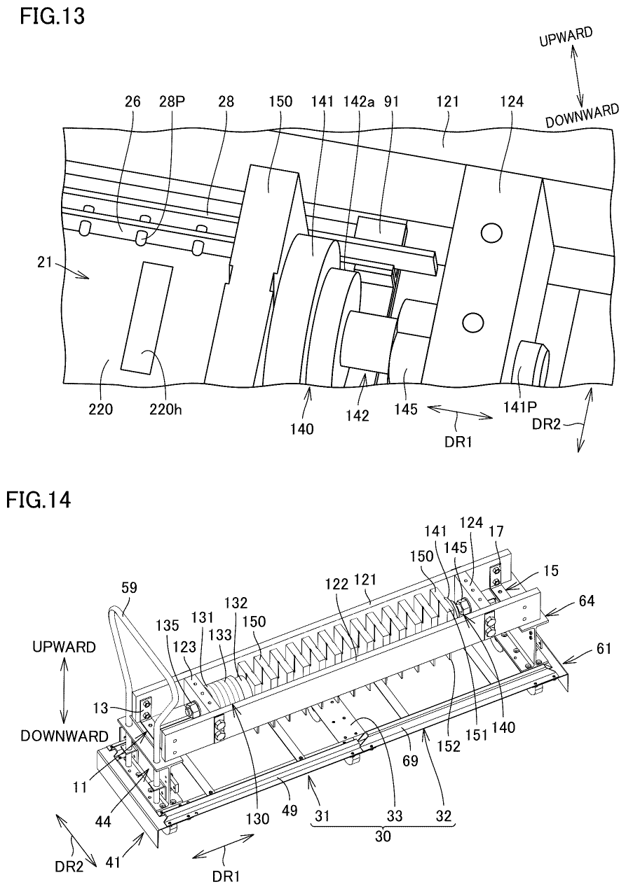

Plate 220 extends along the first direction. As will be described later, heat dissipation plates 150 (see FIG. 13) and the power semiconductor elements (see FIG. 15) are alternately disposed on plate 220. Plate 220 is provided with a plurality of holes 220h. The plurality of holes 220h are disposed side by side at intervals in the first direction. The plurality of holes 220h are provided at positions where heat dissipation plates 150 are disposed. Protruding pieces 152 (described later) of heat dissipation plate 150 are inserted into the plurality of holes 220h.

Side wall 221 is provided so as to rise upward from one end of plate 220 in the second direction. Side wall 222 is provided so as to rise upward from the other end of plate 220 in the second direction.

Flange 223 is provided so as to protrude from an upper end of side wall 221 toward one side in the second direction. Flange 223 is fixed to insulating frame 121 when support fitting 21 is attached to the pair of insulating frames 121 and 122.

Flange 224 is provided so as to protrude from an upper end of side wall 222 toward the other side in the second direction. Flange 224 is fixed to insulating frame 122 when support fitting 21 is attached to the pair of insulating frames 121 and 122.

Pressure bonding mechanism supports 23 and 24 are parts for supporting a pressure bonding mechanism 130 (see FIG. 11) and a pressure bonding mechanism 140 (see FIG. 13) (described later). Pressure bonding mechanism supports 23 and 24 are fixed to plate 220.

Pressure bonding mechanism supports 23 and 24 are disposed side by side at intervals in the first direction. Pressure bonding mechanism support 23 is disposed on one end of plate 220 located on one side in the first direction. Pressure bonding mechanism support 24 is disposed on the other end of plate 220 located on the other side in the first direction. In the first direction, the plurality of holes 220h are disposed between pressure bonding mechanism supports 23 and 24.

Guides 25 and 26 extend along the first direction. Guides 25 and 26 are fixed to body 22 (specifically, plate 220) inside side walls 221 and 222. Guides 25 and 26 are disposed away from side walls 221 and 222.

Guide 25 is disposed so as to face side wall 221 in the second direction, and a gap S1 is provided between guide 25 and side wall 221. Guide 26 is disposed so as to face side wall 222 in the second direction, and a gap S2 is provided between guide 26 and side wall 222.

Guides 25 and 26 have a thickness in the second direction and have flat plates extending along the first direction. Guides 25 and 26 are disposed side by side at intervals in the second direction. When power converter 200 is manufactured, heat dissipation plates 150 and power semiconductor elements 160 are laminated and arranged in the first direction between guides 25 and 26. When heat dissipation plates 150 and power semiconductor elements 160 having been laminated and arranged are pressure-bonded to each other in the first direction, guides 25 and 26 guide the movement of heat dissipation plates 150 and power semiconductor elements 160 in the first direction.

Flat plate of guide 25 is provided with a plurality of holes 25h. The plurality of holes 25h are disposed side by side at intervals in the first direction. Flat plate of guide 26 is provided with a plurality of holes 26h. The plurality of holes 26h are provided at positions corresponding to the plurality of holes 25h. The plurality of holes 26h are disposed side by side at intervals in the first direction so as to face the plurality of holes 25h in the second direction.

Positioning member 27 is detachably provided on support fitting 21. Positioning member determines a position where at least heat dissipation plate 150 is disposed in a state where positioning member 27 is attached to support fitting 21. Positioning member 27 includes a first member 28 and a second member 29.

First member 28 has a flat plate shape having a thickness in the second direction and extends along the second direction. First member 28 has a main surface 28a facing the flat plate of guide 25 in the attached state. Main surface 28a is provided with a plurality of pins 28 P.

The plurality of pins 28P are provided so as to protrude in a normal direction of main surface 28a. The plurality of pins 28P are disposed side by side at intervals in the second direction. The plurality of pins 28P are inserted into the plurality of holes 25h in the attached state.

Second member 29 has a flat plate shape having a thickness in the second direction and extends along the second direction. Second member 29 has a main surface 29a facing the flat plate of guide 26 in an attached state. Main surface 29a is provided with a plurality of pins 29 P.

The plurality of pins 29P are provided so as to protrude in a normal direction of main surface 29a. The plurality of pins 29P are disposed side by side at intervals in the second direction. The plurality of pins 29P are provided at positions corresponding to the plurality of pins 28P. The plurality of pins 29P are inserted into the plurality of holes 26h in the attached state.

Heat dissipation plate 150 or power semiconductor element 160 is disposed between pins 28P adjacent in the first direction and between pins 29P adjacent in the first direction to position heat dissipation plate 150 and power semiconductor element 160.

The pair of fixing members 91 is for fixing the position of first member 28 in the second direction in a state where first member 28 is assembled to guide 25. Specifically, in a state where first member 28 is assembled to guide 25 so that the plurality of pins 28P enter the plurality of holes 25h, the pair of fixing members 91 is disposed between side wall 221 and first member 28.

In addition, the pair of fixing members 91 are provided so as to be attachable to attachment holes 28h provided on one end and the other end of first member 28 in the first direction. The pair of fixing members 91 are fixed to attachment holes 28h in a storage state of assembly jig 1 described later.

Similarly, the pair of fixing members 92 is for fixing the position of second member 29 in the second direction in a state where second member 29 is assembled to guide 26. Specifically, in a state where first member 29 is assembled to guide 26 so that the plurality of pins 29P enter the plurality of holes 26h, the pair of fixing members 92 are disposed between side wall 222 and second member 29.

In addition, the pair of fixing members 92 are provided so as to be attachable to attachment holes 29h provided on one end and the other end of second member 29 in the first direction. The pair of fixing members 92 are fixed to attachment holes 29h in the storage state of the assembly jig 1.

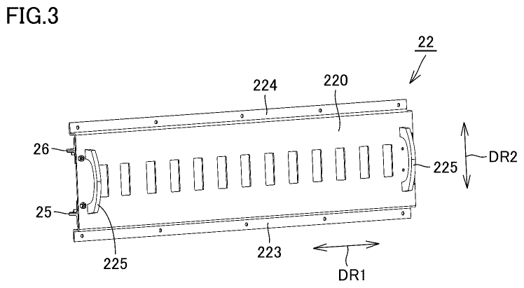

FIG. 3 is a view of the support fitting according to the embodiment as viewed from a back surface. As illustrated in FIG. 3, a pair of handles 225 are provided on the back surface of support fitting 21. Support fitting 21 can be gripped and moved by using the pair of handles 225. Thus, support fitting 21 can be easily attached and detached.

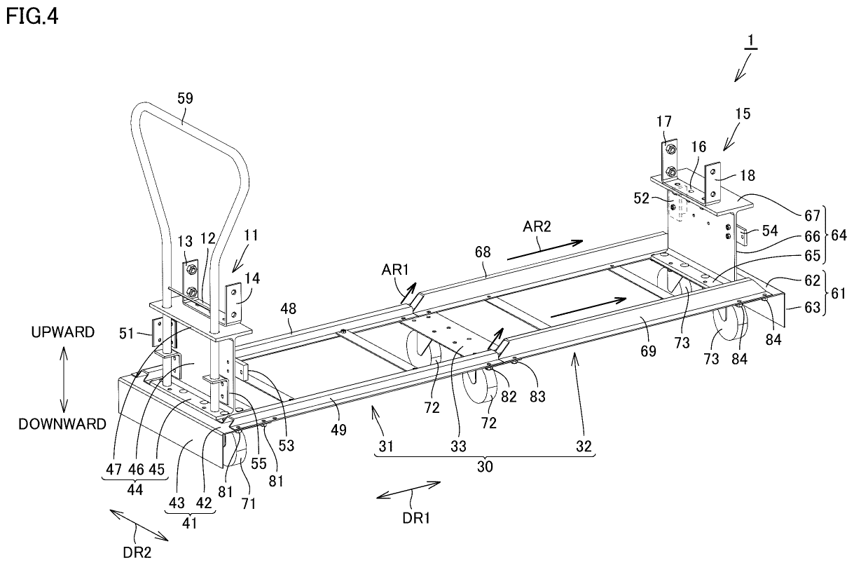

FIG. 4 is a view for describing an operation when the foundation of the assembly jig for the power converter according to the embodiment is made compact.

When foundation 30 is made compact, first, the fastening of the pair of longitudinal members 48 and 49 and connection member 33 by fastening member 82 is released. This enables first unit 31 to relatively slide against second unit 32 as described above.

In this state, first unit 31 is moved toward the other side in the first direction so as to approach second unit 32. At this time, as indicated by an arrow AR1, slopes 68a and 69a described above guide the movement of the pair of longitudinal members 48 and 49 so that the pair of longitudinal members 48 and 49 rides over the pair of longitudinal members 68 and 69 of second unit 32. In this state, as indicated by an arrow AR2, by further moving first unit 31 toward the other side in the first direction, the pair of longitudinal members 68 and 69 can be disposed above the pair of longitudinal members 48 and 49 in an overlapping manner. After the pair of longitudinal members 68 and 69 is disposed above the pair of longitudinal members 48 and 49 in an overlapping manner, longitudinal member 48 and longitudinal member 68 are preferably fastened and fixed to each other with a fastening member such as a bolt in order to prevent falling. Longitudinal member 48 and longitudinal member 68 are fastened to connection member 33. Similarly, longitudinal member 49 and longitudinal member 69 may be fastened and fixed, and in this case as well, longitudinal member 49 and longitudinal member 69 are fastened to connection member 33.

FIG. 5 is a view illustrating a state where the assembly jig for the power converter according to the embodiment is made compact. As illustrated in FIG. 5, positioning member 27 and support fitting 21 are attached to positioning member attachment portions 51 and 52 and support fitting attachment portions 53 and 54 in a state where the pair of longitudinal members 48 and 49 is disposed above the pair of longitudinal members 68 and 69 in an overlapping manner.

Specifically, positioning member 27 is attached to positioning member attachment portions 51 and 52 so as to straddle support base 44 and support base 64 on one side in the second direction. At this time, first member 28 of positioning member 27 is attached to positioning member attachment portions 51 and 52 in a state where the pair of fixing members 91 is fixed. Similarly, second member 29 of positioning member 27 is attached to positioning member attachment portions 51 and 52 in a state where the pair of fixing members 92 is fixed.

Support fitting 21 is attached to support fitting attachment portions 53 and 54 so as to straddle support base 44 and support base 64 on the other side in the second direction.

Assembly jig 1 can be stored in a predetermined place without taking up a space before or after manufacturing power converter 200 by making assembly jig 1 compact in this manner.

### (Method for Manufacturing Power Converter)

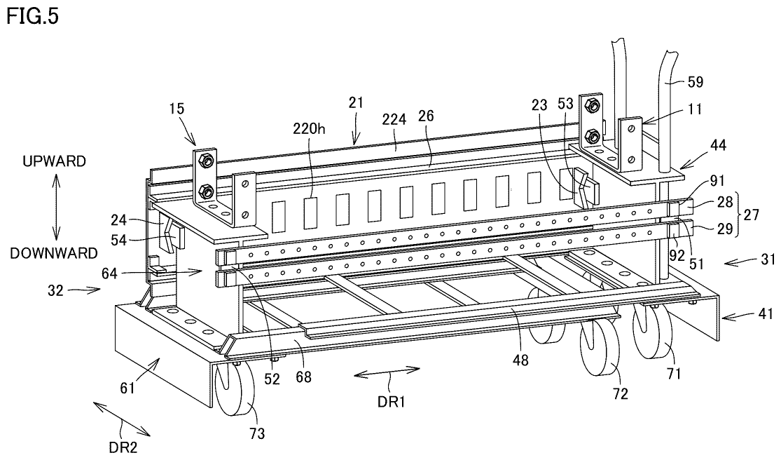

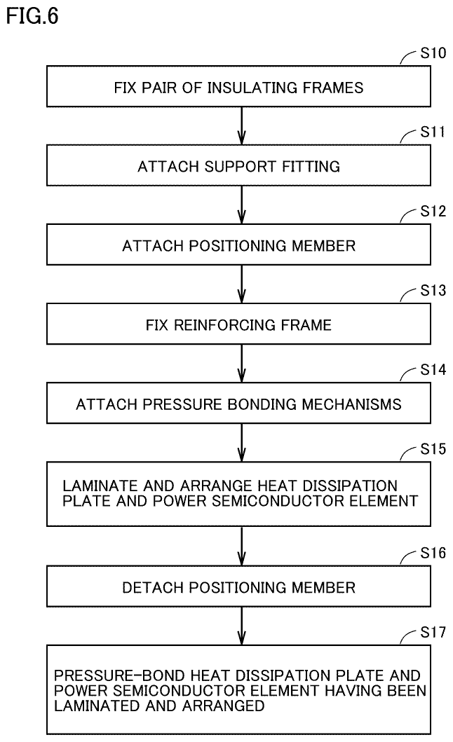

FIG. 6 is a flowchart illustrating steps of manufacturing the power converter according to the embodiment. FIGS. 7 to 19 illustrate each step of manufacturing illustrated in FIG. 6, a state after a predetermined step, or heat dissipation plates or power semiconductor elements used in a power conversion layer. In FIGS. 7 to 10, casters 71, 72, and 73 of assembly jig 1 are omitted for convenience.

A method for manufacturing power converter 200 according to the embodiment will be described with reference to FIGS. 6 to 19.

As shown in FIG. 6, the method for manufacturing the power converter includes a step of fixing the pair of insulating frames 121 and 122 (S10), a step of attaching the support fitting 21 (S11), a step of attaching positioning member 27 (S13), a step of attaching the pressure bonding mechanisms (S14), a step of laminating and arranging heat dissipation plate 150 and power semiconductor element 160 (S15), a step of detaching positioning member 27 (S16), and a step of pressing heat dissipation plate 150 and power semiconductor element 160 having been laminated and arranged (S17).

FIG. 7 is a view illustrating the step of fixing the pair of insulating frames illustrated in FIG. 6. As illustrated in FIGS. 6 and 7, in manufacturing power converter 200, first, in step (S10), the pair of insulating frames 121 and 122 is fixed to the pair of fixing portions 11 and 15 disposed to face each other in the first direction so as to face each other in the second direction.

Specifically, as described above, assembly jig 1 including the pair of fixing portions 11 and 15 and foundation 30 supporting the pair of fixing portions 11 and 15 is prepared, and the pair of insulating frames 121 and 122 is fixed to the pair of fixing portions 11 and 15 disposed apart from each other in the first direction in a state where first unit 31 is unable to relatively slide.

Insulating frame 121 is fixed so as to straddle side wall 13 and side wall 17 outside side wall 13 and side wall 17. Insulating frame 122 is fixed so as to straddle side wall 14 and side wall 18 outside side wall 14 and side wall 18 described above.

The pair of insulating frames 121 and 122 includes an insulating member such as fiber reinforced plastic (FRP).

FIG. 8 is a view illustrating the step of attaching the support fitting illustrated in FIG. 6. As illustrated in FIGS. 6 and 8, in step (S11), support fitting 21 is attached to the pair of insulating frames 121 and 122 fixed to the pair of fixing portions 11 and 15 from below.

Specifically, flanges 223 and 224 of support fitting 21 are superposed below insulating frames 121 and 122 and fastened to the fastening member.

FIG. 9 is a view illustrating the step of attaching the positioning member illustrated in FIG. 6. As illustrated in FIGS. 6 and 9, in step (S12), positioning member 27 is attached to support fitting 21 attached to the pair of insulating frames 121 and 122.

Specifically, first member 28 of positioning member 27 is disposed in gap S1 of support fitting 21, and the plurality of pins 28P are inserted into the plurality of holes 25h provided in guide 25. In this state, on both ends of first member 28 in the first direction, fixing member 91 is disposed between first member 28 and side wall 221, and first member 28 is fixed.

Similarly, second member 29 of positioning member 27 is disposed in gap S2 of support fitting 21, and the plurality of pins 29P are inserted into the plurality of holes 26h provided in guide 26. In this state, on both ends of first member 28 in the first direction, fixing member 92 (see FIG. 11) is disposed between second member 29 and side wall 222, and second member 29 is fixed.

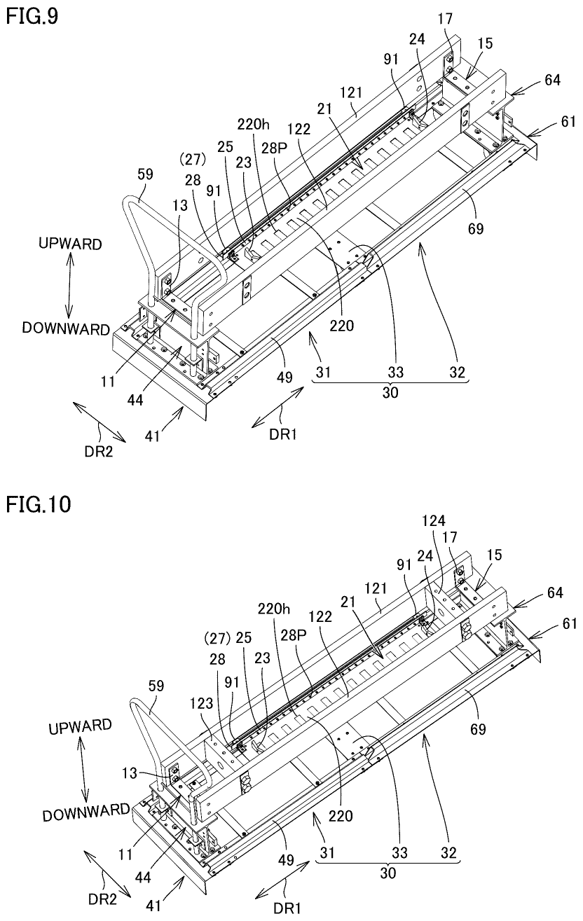

FIG. 10 is a view illustrating a step of fixing reinforcing frames illustrated in FIG. 6. As illustrated in FIGS. 6 and 10, in step (S13), reinforcing frames 123 and 124 are fixed to the pair of insulating frames 121 and 122. Specifically, the pair of reinforcing frames 123 and 124 is fixed on both outer sides of support fitting 21 in the first direction.

Reinforcing frame 123 is disposed between an end of support fitting 21 located on one side in the first direction and fixing portion 11. Reinforcing frame 123 is fixed to the pair of insulating frames 121 and 122 in a state where an insulation distance is secured from fixing portion 11. Reinforcing frame 123 extends along the second direction and is fixed so as to connect the pair of insulating frames 121 and 122.

Reinforcing frame 124 is disposed between an end of support fitting 21 located on the other side in the first direction and fixing portion 15. Reinforcing frame 124 is fixed to the pair of insulating frames 121 and 122 in a state where an insulation distance is secured from fixing portion 15. Reinforcing frame 124 extends along the second direction and is fixed so as to connect the pair of insulating frames 121 and 122.

Reinforcing frames 123 and 124 include a metal member. As described later, reinforcing frames 123 and 124 have sufficient strength against reaction force from heat dissipation plate 150 and power semiconductor element 160 having been pressure-bonded.

Subsequently, as illustrated in FIG. 6 again, in step (S14), pressure bonding mechanisms 130 and 140 are attached to both ends of support fitting 21 in the first direction between the pair of insulating frames 121.

FIG. 11 is a view illustrating a first step of the step of attaching the pressure bonding mechanisms illustrated in FIG. 6. As illustrated in FIG. 11, in step (S14), first, in the first step, pressure bonding mechanism 130 is attached to an end of support fitting 21 on one side in the first direction.

Pressure bonding mechanism 130 includes a first pressing member 131, a second pressing member 132, an elastic biasing member 133, and a fastening member 135. First pressing member 131 includes a pin 131P that penetrates reinforcing frame 123 and a support that supports elastic biasing member 133. As elastic biasing member 133, for example, a disc spring can be employed.

When pressure bonding mechanism 130 is attached, first pressing member 131 is fixed to reinforcing frame 123 in a state where elastic biasing member 133 is assembled to first pressing member 131. First pressing member 131 is fixed in a state of being in contact with reinforcing frame 123. Specifically, pin 131P is inserted into a through hole provided in reinforcing frame 123, and first pressing member 131 is fixed to reinforcing frame 123 by using fastening member 135.

In a state where heat dissipation plate 150 and second pressing member 132 are combined, heat dissipation plate 150 is positioned on support fitting 21 such that elastic biasing member 133 is sandwiched between first pressing member 131 and second pressing member 132.

FIG. 12 is a perspective view illustrating the heat dissipation plate used in the power converter according to the embodiment. As illustrated in FIG. 12, heat dissipation plate 150 includes a body 151 having a substantially rectangular parallelepiped shape and protruding piece 152.

Body 151 has a first main surface 151a and a second main surface 151b facing each other in a thickness direction. Note that the thickness direction is substantially parallel to the first direction in a state where heat dissipation plate 150 is disposed on (supported by) support fitting 21.

Each of first main surface 151a and second main surface 151b is provided at a center in a width direction with a groove 151c extending to substantially a center in a height direction. The width direction is substantially parallel to the second direction in a state where heat dissipation plate 150 is disposed on (supported by) support fitting 21. The height direction is substantially parallel to the vertical direction in a state where heat dissipation plate 150 is disposed on (supported by) support fitting 21. That is, groove 151c extends in the vertical direction.

Heat dissipation plate 150 includes a metal member having good thermal conductivity and electrical conductivity. As the metal member, for example, a metal such as aluminum or copper, an alloy thereof, or the like can be adopted.

As described above, when heat dissipation plate 150 and pressing member 132 are combined, a protrusion (not illustrated) provided on pressing member 132 is inserted into groove 151c provided on first main surface 151a located on a side of pressing member 132.

As described above, when heat dissipation plate 150 is positioned on support fitting 21 such that elastic biasing member 133 is sandwiched between pressing member 131 and pressing member 132, protruding piece 152 of heat dissipation plate 150 is inserted into hole 220h located on one side farthest in the first direction. At this time, heat dissipation plate 150 (specifically, body 151) is disposed between pin 28P and pin 29P located on one side farthest in the first direction and pin 28P and pin 29P adjacent to pin 28P and pin 29P located on the one side farthest in the first direction.

FIG. 13 is a view illustrating a second step of the step of attaching the pressure bonding mechanisms illustrated in FIG. 6. As illustrated in FIG. 13, in the second step of step (S14), pressure bonding mechanism 140 is attached to an end of support fitting 21 on one side in the first direction.

Pressure bonding mechanism 140 includes a third pressing member 141, a pin member 142, and a fastening member 145. Pin member 142 has a top 142a and a shaft 142P. Top 142a has, for example, a spherical seat.

When pressure bonding mechanism 140 is attached, pin member 142 is fixed to reinforcing frame 124. Specifically, shaft 142P is inserted into a through hole provided in reinforcing frame 124 such that top 142a is positioned on one side (on a side of support fitting 21) in the first direction with respect to reinforcing frame 124, and pin member 142 is fixed to reinforcing frame 124 by using fastening member 145. At this time, since top 142a has a spherical seat as described above, pin member 142 is preferably shifted to the other side in the first direction.

In a state where heat dissipation plate 150 and third pressing member 141 are combined, heat dissipation plate 150 is positioned on support fitting 21 such that third pressing member 141 is sandwiched between heat dissipation plate 150 and top 142a.

Specifically, in a state where heat dissipation plate 150 and third pressing member 141 are combined, protruding piece 152 of heat dissipation plate 150 is inserted into hole 220h located on the other side farthest in the first direction. At this time, heat dissipation plate 150 (specifically, body 151) is disposed between pin 28P and pin 29P located on the other side farthest in the first direction and pin 28P and pin 29P adjacent to pin 28P and pin 29P located on the other side farthest in the first direction. At this time, pin member 142 is moved to one side in the first direction, and pressure bonding mechanism 140 is positioned at a predetermined position.

Subsequently, as illustrated in FIG. 6 again, in step (S15), heat dissipation plates 150 and power semiconductor elements 160 are alternately laminated and arranged on support fitting 21 in the first direction between the pair of insulating frames 121 and 122 and between pressure bonding mechanisms 130 and 140 in the first direction.

FIG. 14 is a view illustrating a first step of the step of laminating and arranging the heat dissipation plate and the power semiconductor element illustrated in FIG. 6.

As illustrated in FIG. 14, in step (S15), first, in a first step, heat dissipation plates 150 are disposed along the first direction at predetermined intervals by using positioning member 27. Specifically, protruding pieces 152 of the plurality of heat dissipation plates 150 are inserted into the plurality of holes 220h. At this time, each of the plurality of heat dissipation plates 150 is disposed between predetermined pin 28P and pin 29P and pin 28P and pin 29P adjacent to predetermined pin 28P and pin 29P on one side in the first direction. Accordingly, the plurality of heat dissipation plates 150 are positioned.

FIG. 15 is a perspective view illustrating the power semiconductor element used in the power converter according to the embodiment.

As illustrated in FIG. 15, power semiconductor element 160 has a substantially cylindrical shape. The power semiconductor element has a first main surface 160a and a second main surface 160b facing each other in a thickness direction. Note that the thickness direction is substantially parallel to the first direction when power semiconductor elements 160 and heat dissipation plates 150 are laminated and arranged on support fitting 21.

A protrusion 160c is provided at a center of each of first main surface 160a and second main surface 160b. Protrusion 160c is provided to be engaged with heat dissipation plate 150 (specifically, groove 151c).

FIG. 16 is a view illustrating a second step of the step of laminating and arranging the heat dissipation plate and the power semiconductor element illustrated in FIG. 6.

As illustrated in FIG. 16, in the second step of step (S15), power semiconductor elements 160 are disposed in each gap between heat dissipation plates 150 adjacent to each other in the first direction.

Specifically, in heat dissipation plates 150 adjacent to each other, protrusions 160c provided on first main surface 160a and second main surface 160b of power semiconductor element 160 are inserted from above into grooves 151c provided on first main surface 151a and second main surface 151b facing each other in the first direction. Thereafter, power semiconductor element 160 is moved downward until protrusions 160c abut against base ends of grooves 151c.

As described above, in the second step of step (S15), protrusions 160c are inserted into grooves 151c, and the downward movement of power semiconductor element 160 is guided. Furthermore, power semiconductor element 160 is positioned by grooves 151c. Note that power semiconductor element 160 may be positioned by positioning member 27.

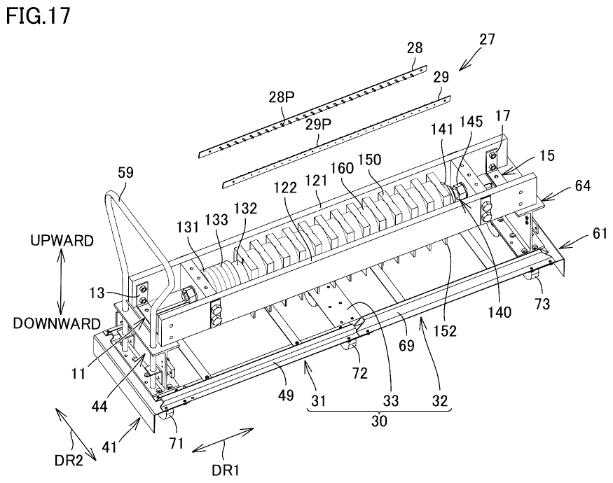

FIG. 17 is a view illustrating the step of detaching the positioning member illustrated in FIG. 6. As illustrated in FIGS. 6 and 17, in step (S16), positioning member 27 is detached from support fitting 21. Step (S16) is performed after step (S15) and before step (S17).

When positioning member 27 is detached from support fitting 21, fixing member 91 disposed between first member 28 and side wall 221 is detached on one side in the second direction, and first member 28 is moved to one side in the second direction to extract the plurality of pins 28P from the plurality of holes 25h provided in guide 25. Thereafter, first member 28 is moved upward.

On the other side in the second direction, fixing member 92 disposed between second member 29 and side wall 222 is detached, and second member 29 is moved to the other side in the second direction to extract the plurality of pins 29P from the plurality of holes 26h provided in guide 26. Thereafter, second member 29 is moved upward.

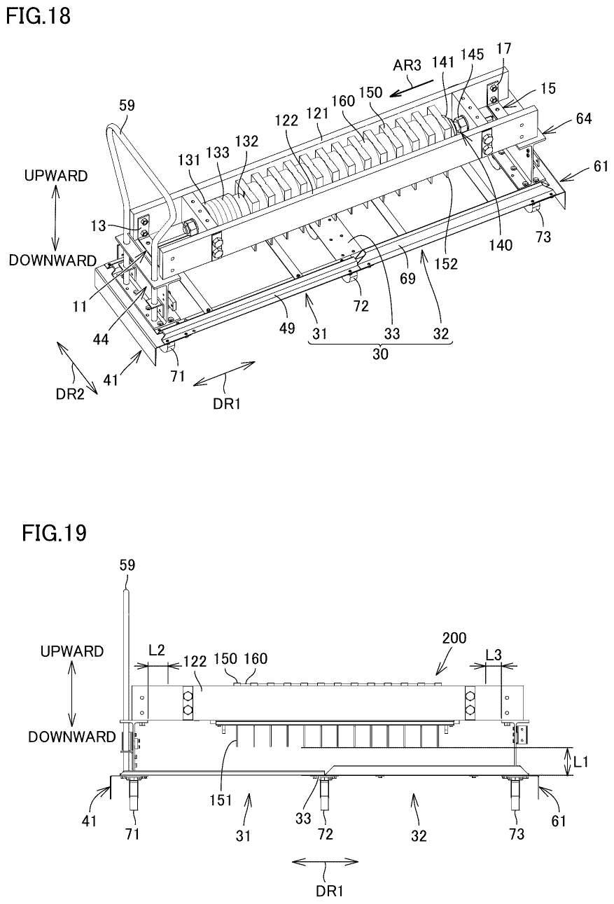

FIG. 18 is a view illustrating a step of pressure-bonding the heat dissipation plate and the power semiconductor element having been laminated and arranged, illustrated in FIG. 6.

As illustrated in FIGS. 6 and 18, in step (S17), heat dissipation plates 150 and power semiconductor elements 160 laminated and arranged on support fitting 21 are pressure-bonded to each other in the first direction by pressure bonding mechanisms 130 and 140.

Specifically, a fastening force of fastening members 135 and 145 is increased to reach a predetermined reference value. At this time, heat dissipation plates 150 and power semiconductor elements 160 are pressure-bonded to each other in the first direction (for example, the direction of an arrow AR3 in FIG. 18), and the movement of heat dissipation plates 150 and power semiconductor elements 160 in the first direction is guided by guides 25 and 26. As a result, the orientation of heat dissipation plates 150 and power semiconductor elements 160 can be stably maintained.

FIG. 19 is a side view illustrating a state after the step of pressure-bonding illustrated in FIG. 6. As illustrated in FIG. 19, in a state after step (S17), that is, in a pressure-bonded state where heat dissipation plates 150 and power semiconductor element 160 laminated and arranged on support fitting 21 are in pressure-bonded to each other in the first direction, connection member 33 is located below support fitting 21 and faces any one of protruding pieces 152 of the plurality of heat dissipation plates 150 in the vertical direction with a distance. At this time, heat dissipation plates 150 (specifically, protruding pieces 152) and connection member 33 facing each other are disposed so as to secure a distance L1 longer than or equal to a spatial distance for insulating parts having mutually different potentials in the vertical direction.

In the pressure-bonded state, pressure bonding mechanism 130 located on one side in the first direction and fixing portion 11 located on one side in the first direction of the pair of fixing portions 11 and 15 are disposed side by side in the first direction so as to secure a distance L2 longer than or equal to a spatial distance for insulating parts having mutually different potentials.

Similarly, in the pressure-bonded state, pressure bonding mechanism 140 located on the other side in the first direction and fixing portion 15 located on the other side in the first direction of the pair of fixing portions 11 and 15 are disposed side by side in the first direction so as to secure a distance L3 longer than or equal to a spatial distance for insulating parts having mutually different potentials.

Since insulation between power converter 200 and assembly jig 1 is secured as described above, an energization test can be performed in a state where power converter 200 is disposed in assembly jig 1. Casters 71, 72, and 73 are provided on foundation 30 of assembly jig 1, and foundation 30 is movably provided. Therefore, assembled power converter 200 can be moved together with assembly jig 1 in a state where being disposed in assembly jig 1. As a result, power converter 200 can be easily moved to a predetermined place. For example, power converter 200 can be easily moved from an assembly position to an energization test position.

Power converter 200 can be manufactured through the above steps. By manufacturing power converter 200 by using assembly jig 1 as described above, heat dissipation plates 150 and power semiconductor elements 160 can be laminated and arranged in a horizontal direction. Therefore, collapse of laminated heat dissipation plates 150 and power semiconductor elements 160 can be suppressed as compared with a case where heat dissipation plates 150 and power semiconductor elements 160 are laminated and arranged in the vertical direction. Accordingly, safety of assembly can be ensured.

In addition, as compared with a case where the heat dissipation plates and the power semiconductor elements are laminated and arranged in the vertical direction, heat dissipation plates 150 and power semiconductor elements 160 are not laminated and arranged in a balanced manner so as not to collapse. Therefore, assembly workability can be improved.

The embodiment disclosed herein is illustrative in all respects and not restrictive. The scope of the present invention is indicated by the claims, and all modifications within the meaning and scope of the claims are included in the present invention.

REFERENCE SIGNS LIST

1: assembly jig, 11: fixing portion, 12: flat plate, 13, 14: side wall, 15: fixing
portion, 16: flat plate, 17, 18: side wall, 20: support unit, 21: support fitting, 22: body,
23, 24: pressure bonding mechanism support, 25, 26: guide, 25h, 26h: hole, 27:
positioning member, 28: first member, 28a: main surface, 28P: pin, 29: second
member, 29a: main surface, 29P: pin, 30: foundation, 31: first unit, 32: second unit, 33:
connection member, 41: base, 42: flat plate, 43: side wall, 44: support base, 45: bottom
plate, 46: upright wall, 47: upper plate, 48, 49: longitudinal member, 51, 52:
positioning member attachment portion, 53, 54: support fitting attachment portion, 61:
base, 62: flat plate, 63: side wall, 64: support base, 65: bottom plate, 66: upright wall,
67: upper plate, 68, 69: longitudinal member, 68a, 69a: slope, 71, 72, 73: caster, 81, 82,
84: fastening member, 91, 92: fixing member, 121, 122: insulating frame, 123, 124:
reinforcing frame, 130: pressure bonding mechanism, 131: first pressing member,
131P: pin, 132: second pressing member, 133: elastic biasing member, 135: fastening
member, 140: pressure bonding mechanism, 141: third pressing member, 142: pin
member, 142P: shaft, 142a: top, 145: fastening member, 150: heat dissipation plate,
151: body, 151a: first main surface, 151b: second main surface, 151c: groove, 152:
protruding piece, 160: power semiconductor element, 160a: first main surface, 160b:
second main surface, 160c: protrusion, 200: power converter, 220: plate, 220h: hole,
221, 222: side wall, 223, 224: flange, 225: handle, L1, L2, L3: distance, S1, S2: gap

1. An assembly jig for a power converter, the assembly jig comprising:
a pair of fixing portions disposed to face each other in a first direction orthogonal to a vertical direction; and
a support fitting provided so as to be attachable from below to a pair of insulating frames fixed to the pair of fixing portions so as to face each other in a second direction orthogonal to the vertical direction and the first direction, the support fitting supporting a heat dissipation plate and a power semiconductor element to be alternately laminated and arranged in the first direction between the pair of insulating frames in an attached state where the support fitting is attached to the pair of insulating frames,
wherein the support fitting includes a guide to guide movement of the heat dissipation plate and the power semiconductor element in the first direction when the heat dissipation plate and the power semiconductor element having been laminated and arranged are pressure-bonded to each other in the first direction.

2. The assembly jig for a power converter according to claim 1, further comprising a positioning member to be detachably attached to the support fitting and determine a position where at least the heat dissipation plate is disposed in a state where the positioning member is attached to the support fitting.

3. The assembly jig for a power converter according to claim 2, further comprising a foundation to support the pair of fixing portions,
wherein the foundation is provided with a support fitting attachment portion to attach and store the support fitting, and a positioning member attachment portion to attach and store the positioning member.

4. The assembly jig for a power converter according to claim 1, further comprising a foundation to support the pair of fixing portions,
wherein the foundation includes
a first unit located on one side in the first direction, the first unit supporting one of the pair of fixing portions,
a second unit located on another side in the first direction, the second unit supporting another one of the pair of fixing portions, and
a lock mechanism,
the first unit is provided to be relatively slidable against the second unit in the first direction, and
the lock mechanism is provided to be switchable between a state that enables the first unit to relatively slide and a state that disables the first unit to relatively slide.

5. The assembly jig for a power converter according to claim 1, further comprising a foundation to support the pair of fixing portions,
wherein
the foundation includes a portion located below the support fitting in the attached state,
in a pressure-bonded state where pressure bonding mechanisms are attached to both ends of the support fitting in the first direction between the pair of insulating frames and the heat dissipation plate and the power semiconductor element are pressure-bonded to each other in the first direction between the pressure bonding mechanisms in the first direction,
a portion of the pressure bonding mechanism located on one side in the first direction and the fixing portion of the pair of fixing portions located on the one side in the first direction are disposed side by side in the first direction with a secured distance longer than or equal to a spatial distance for insulating parts having mutually different potentials,
a portion of the pressure bonding mechanism located on another side in the first direction and the fixing portion of the pair of fixing portions located on the another side in the first direction are disposed side by side in the first direction with a secured distance longer than or equal to a spatial distance for insulating parts having mutually different potentials, and
the heat dissipation plate and the portion of the foundation located below the support fitting are disposed with a secured distance longer than or equal to a spatial distance for insulating parts having mutually different potentials in the vertical direction.

6. A method for manufacturing a power converter, the method comprising:
fixing a pair of insulating frames to a pair of fixing portions disposed to face each other in a first direction orthogonal to a vertical direction so as to face each other in a second direction orthogonal to the vertical direction and the first direction;
attaching a support fitting from below to the pair of insulating frames fixed to the pair of fixing portions;
attaching pressure bonding mechanisms to both ends of the support fitting in the first direction between the pair of insulating frames;
alternately laminating and arranging a heat dissipation plate and a power semiconductor element on the support fitting in the first direction between the pair of insulating frames and between the pressure bonding mechanisms in the first direction; and
pressure-bonding the heat dissipation plate and the power semiconductor element that are laminated and arranged on the support fitting to each other in the first direction by the pressure bonding mechanisms,
wherein in the pressure-bonding, movement of the heat dissipation plate and the power semiconductor element in the first direction is guided by a guide included in the support fitting.

7. The method for manufacturing a power converter according to claim 6, further comprising attaching a positioning member to determine a position where at least the heat dissipation plate is disposed to the support fitting attached to the pair of insulating frames,
wherein the laminating and arranging includes
arranging the heat dissipation plates along the first direction at a predetermined interval by using the positioning member, and
arranging the power semiconductor element in each gap between the heat dissipation plates adjacent to each other in the first direction.

8. The method for manufacturing a power converter according to claim 7, further comprising detaching the positioning member from the support fitting before the pressure-bonding.

9. The method for manufacturing a power converter according to claim 7, wherein
the power semiconductor element includes a protrusion to protrude in the first direction,
the heat dissipation plate includes a groove to extend in the vertical direction, and
in the arranging of the power semiconductor element in the each gap between the heat dissipation plates adjacent to each other in the first direction, the protrusion is inserted into the groove to guide movement of the power semiconductor element in the vertical direction.

10. The method for manufacturing a power converter according to claim 7, wherein
in the fixing of the pair of insulating frames, an assembly jig having a pair of fixing portions and a foundation to support the pair of fixing portions is used,
the foundation includes a portion located below the support fitting in an attached state where the support fitting is attached to the pair of insulating frames,
in the pressure-bonding, in a pressure-bonded state where the heat dissipation plate and the power semiconductor element having been laminated and arranged on the support fitting are pressure-bonded to each other in the first direction by the pressure bonding mechanisms,
a portion of the pressure bonding mechanism located on one side in the first direction and the fixing portion of the pair of fixing portions located on the one side in the first direction are disposed side by side in the first direction with a secured distance longer than or equal to a spatial distance for insulating parts having mutually different potentials,
a portion of the pressure bonding mechanism located on another side in the first direction and the fixing portion of the pair of fixing portions located on the another side in the first direction are disposed side by side in the first direction with a secured distance longer than or equal to a spatial distance for insulating parts having mutually different potentials, and
the heat dissipation plate and the portion of the foundation located below the support fitting are arranged with a secured distance longer than or equal to a spatial distance for insulating parts having mutually different potentials in the vertical direction.

11. The assembly jig for a power converter according to claim 2, further comprising a foundation to support the pair of fixing portions,
wherein the foundation includes
a first unit located on one side in the first direction, the first unit supporting one of the pair of fixing portions,
a second unit located on another side in the first direction, the second unit supporting another one of the pair of fixing portions, and
a lock mechanism,
the first unit is provided to be relatively slidable against the second unit in the first direction, and
the lock mechanism is provided to be switchable between a state that enables the first unit to relatively slide and a state that disables the first unit to relatively slide.

12. The assembly jig for a power converter according to claim 2, further comprising a foundation to support the pair of fixing portions,
wherein
the foundation includes a portion located below the support fitting in the attached state,
in a pressure-bonded state where pressure bonding mechanisms are attached to both ends of the support fitting in the first direction between the pair of insulating frames and the heat dissipation plate and the power semiconductor element are pressure-bonded to each other in the first direction between the pressure bonding mechanisms in the first direction,
a portion of the pressure bonding mechanism located on one side in the first direction and the fixing portion of the pair of fixing portions located on the one side in the first direction are disposed side by side in the first direction with a secured distance longer than or equal to a spatial distance for insulating parts having mutually different potentials,
a portion of the pressure bonding mechanism located on another side in the first direction and the fixing portion of the pair of fixing portions located on the another side in the first direction are disposed side by side in the first direction with a secured distance longer than or equal to a spatial distance for insulating parts having mutually different potentials, and
the heat dissipation plate and the portion of the foundation located below the support fitting are disposed with a secured distance longer than or equal to a spatial distance for insulating parts having mutually different potentials in the vertical direction.

13. The method for manufacturing a power converter according to claim 8, wherein
the power semiconductor element includes a protrusion to protrude in the first direction,
the heat dissipation plate includes a groove to extend in the vertical direction, and
in the arranging of the power semiconductor element in the each gap between the heat dissipation plates adjacent to each other in the first direction, the protrusion is inserted into the groove to guide movement of the power semiconductor element in the vertical direction.

14. The method for manufacturing a power converter according to claim 8, wherein Y
in the fixing of the pair of insulating frames, an assembly jig having a pair of fixing portions and a foundation to support the pair of fixing portions is used,
the foundation includes a portion located below the support fitting in an attached state where the support fitting is attached to the pair of insulating frames,
in the pressure-bonding, in a pressure-bonded state where the heat dissipation plate and the power semiconductor element having been laminated and arranged on the support fitting are pressure-bonded to each other in the first direction by the pressure bonding mechanisms,
a portion of the pressure bonding mechanism located on one side in the first direction and the fixing portion of the pair of fixing portions located on the one side in the first direction are disposed side by side in the first direction with a secured distance longer than or equal to a spatial distance for insulating parts having mutually different potentials,
a portion of the pressure bonding mechanism located on another side in the first direction and the fixing portion of the pair of fixing portions located on the another side in the first direction are disposed side by side in the first direction with a secured distance longer than or equal to a spatial distance for insulating parts having mutually different potentials, and
the heat dissipation plate and the portion of the foundation located below the support fitting are arranged with a secured distance longer than or equal to a spatial distance for insulating parts having mutually different potentials in the vertical direction.
